(19) United States
(12) Patent Application Publication
(10) Pub. No.: US 2017/0261831 A1
(43) Pub. Date: Sep. 14, 2017

(54) PROCESS AND A DEVICE FOR CONTROLLING SUPERCONDUCTIVITY AND SUPERCONDUCTIVE MATERIALS

(71) Applicants: UNIVERSITE DE STRASBOURG, STRASBOURG (FR); CENTRE NATIONAL DE LA RECHERCHE SCIENTIFIQUE, PARIS (FR); CENTRE INTERNATIONAL DE RECHERCHE AUX FRONTIERES DE LA CHIMIE, STRASBOURG (FR)

(72) Inventor: Thomas EBBESEN, STRASBOURG (FR)

(21) Appl. No.: 15/456,925

(22) Filed: Mar. 13, 2017

Related U.S. Application Data
(60) Provisional application No. 62/307,660, filed on Mar. 14, 2016.

(51) Int. Cl. G02F 1/21; H01L 39/12; H01L 39/24; G02B 26/00

(52) U.S. Cl. CPC G02F 1/21; G02B 26/001; H01L 39/125; H01L 39/24; G02F 2001/213; G02F 2001/217; G02F 2202/32; G02F 2203/10; G02F 2202/16; G02F 2203/15; G02F 2201/34

(57) ABSTRACT

Disclosed is a method to modify the superconductive properties of a potentially or effectively superconductive material. The method includes providing a reflective or photonic structure and placing said superconductive material in or on the structure. The method also includes providing a structure which has an electromagnetic mode which is resonant with a transition in the material and controlling, in particular enhancing, the superconductivity, and thus the mobility of the charge carriers. This results in a higher operating temperature and an increased electrical current in the material, by means of strongly coupling the material to the local electromagnetic vacuum field and exploiting the formation of states of spatial extension corresponding to the mode volume of the electromagnetic resonance. Also disclosed is an electronic, electro-optical or optoelectronic device including superconductive material located in or on a reflective or photonic structure.

### FIELD OF THE INVENTION

Superconductivity has stimulated much interest over the past century due to its technological importance. The loss of electrical resistance depends on temperature and the critical temperature Tc at which superconductivity appears has gradually increased over time since it was first discovered by Heike Kamerlingh Onnes 1911. The discovery of high-Tc materials (with Tc>90° K) in 1986 in ceramic materials was a major milestone since it is possible to operate at liquid nitrogen temperature. The ultimate aim are superconductors that work at room temperature since it would save enormous amount of energy because electrical resistance is the source of huge losses during transport and distribution of electric energy. Therefore, there is a strong demand for significantly improving the Tc, in order to be able to fully exploit the potential use of such materials in the concerned technological fields and technical applications.

Description of the Related Application

In conventional superconductors, the current is carried by bound pairs of electron known as Cooper pairs. According to BSC theory, phonon mediate the pairing and T_{c} is given by:

T_{c}∞ωe^{-1/gN(E}^{_{F}}⁾ (1)

where w is the phonon cut-off frequency of the phonons mediating the electron coupling, g is the electron-phonon coupling strength and N(E_{F}) is the density of states per unit energy at the Fermi level (T. W. Ebbesen, J. S. Tsai, K. Tanigaki, J. Tabuchi, Y. Shimakawa, Y. Kubo, I. Hirosawa and J. Mizuki “Isotope Effect on Superconductivity in Rb3C60” Nature, 355, 620 622 (1992)). The T_{c} dependence on the phonon is complex but it has been observed that bond-softening can lead to an increase in the critical temperature as reported for instance in the case MgB₂ (A. V. Pogrebnyakov, J. M. Redwing, S. Raghavan, V. Vaithyanathan, D. G. Schlom, S. Y. Xu, Qi Li, D. A. Tenne, A. Soukiassian, X. X. Xi, M. D. Johannes, D. Kasinathan, W. E. Pickett, J. S. Wu and J. C. H. Spence “Enhancement of the superconducting transition temperature of MgB₂ by a strain-induced bond-stretching mode softening” Phys. Rev. Lett. 93, 147006 (2004)).

On the other hand, it is known that light and matter can enter into the strong coupling regime by exchanging photons faster than any competing dissipation processes. This can be achieved by placing the material in a confined electromagnetic environment, such as a Fabry-Perot (FP) cavity composed of two parallel mirrors that is resonant with a transition in the material. Strong coupling leads to the formation of two polaritonic states separated by the so-called Rabi splitting [symbol] ω_{R}. According to quantum electrodynamics, in the absence of dissipation, the Rabi splitting is given by:

$$\overline{h} {Ω}_{R} = 2 \sqrt{\frac{\overline{h} ω}{2 {ɛ}_{0} v}} \cdot d \cdot \sqrt{{n}_{ph} + 1} \qquad ( 2 )$$

where [symbol] ω is the cavity resonance or transition energy, ∈₀ the vacuum permittivity, v the mode volume, d the transition dipole moment of the material and nₚₕ the number of photons present in the system. The last term implies that even in the dark, the Rabi splitting [symbol] Ω_{R} has a finite value which is due to the interaction with the vacuum electromagnetic field.

As background state of the art, one can refer to the following documents: Haroche, S. “Cavity quantum electrodynamics” in: J. Dalibard, J. M. Raimond, J. Zinn-Justin (Eds.), Fundamental Systems in Quantum Optics, Les Houches Summer School. Session LIII, North Holland, Amsterdam. 1992/Schwartz, T., Hutchison, J. A., Genet, C. & Ebbesen, T. W. “Reversible switching of ultra-strong coupling” Phys. Rev Lett. 106, 196405 (2011)/Kéna-Cohen, S., Maier, S. A. & Bradley, D. D. C. “Ultrastrongly coupled exciton-polaritons in metal-clad organic semiconductor microcavities” Adv. Opt. Mater. 1, 827-833 (2013)/Hutchison, J. A., Schwartz, T., Genet, C., Devaux, E. & Ebbesen, T. W. “Modifying chemical landscapes by coupling to the vacuum fields” Angew. Chem., Int. Ed. 51, 1592-1596 (2012)/Hutchison, J. A., Liscio, A., Schwartz, T., Canaguier-Durand, A., Genet, C., Palermo, V., Samori, P. & Ebbesen, T. W. “Tuning the work-function via strong coupling” Adv. Mater. 25, 2481-2485 (2013)/A. Shalabney, J. George, J. A. Hutchison, G. Pupillo, C. Genet and T. W. Ebbesen “Coherent coupling of molecular resonators with a microcavity mode” Nature Commun. 6: 5981 (2015)/A. Shalabney, J. George, H. Hiura, J. A. Hutchison, C. Genet, P. Hellwig, T. W. Ebbesen “Enhanced Raman scattering from vibro-polariton hybrid states” Angewandte Chemie Int. Ed. 54, 7971-7975 (2015)/E. Orgiu, J. George, J. A. Hutchison, E. Devaux, J. F. Dayen, B. Doudin, F. Stellacci, C. Genet, J. Schachenmayer, C. Genes, G. Pupillo, P. Samori and T. W. Ebbesen “Conductivity in organic semiconductors hybridized with the vacuum field” Nature Materials 14, 1123-1129 (2015).

From WO 2013/017961, it is known to make use of strong coupling in order to modify the work function of materials (i.e. the energy required to extract an electron from the material) and the rate of chemical reactions.

From WO 2015/008159, it is known to make use of strong coupling in order to modify the electrical properties of an organic or molecular material.

### SUMMARY OF THE INVENTION

Now, the inventors have found, in an unexpected and surprising manner, that the superconductivity of materials can be influenced by strongly coupling said materials to the vacuum field. The Tc of the superconductors is increased by strongly coupling the phonon of the material to an optical mode in the infrared as illustrated in FIG. 1 below. The coupling can occur when the optical mode is resonant with the phonon. Strong coupling occurs even in the dark because it is the zero-point energy of the phonon transition and the cavity mode that generate the strong coupling. The splitting lowers the phonon frequency and the states formed are delocalized over the volume of the optical mode which favours the coupling constant g (equation 1) and therefore superconductivity. These modifications increase Tc.

### BRIEF DESCRIPTION OF THE DRAWINGS

FIG. 1 is a schematic illustration of strong coupling between a cavity mode resonance and the phonon of a superconducting material, inducing the formation of two hybrid states separated by the Rabi energy [symbol] ω_{R}.

FIG. 2 is a simplified schematic representation of an experimental setup allowing to carry out conductivity measurements on a device according to the invention and comprising a strongly coupled superconducting material 2 sandwiched between two mirror like structures 3 and 3′, said material being linked to two electrodes 5 and 5′ for electrical feeding and measurement purposes.

FIG. 3 is a schematic representation showing a device 4 according to an other embodiment of the invention, wherein the photonic structure 1 is a plasmonic surface structure on which the superconducting material 2 is located.

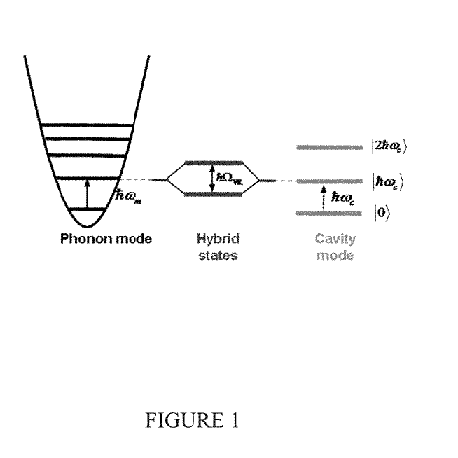

Thus, the main object of the present invention is a method to modify the superconductivity properties of a potentially or effectively superconductive material comprising the steps of providing a reflective or photonic structure and of placing said material in or on said structure, method characterized in that it consists further in providing a structure which has an electromagnetic mode which is by design, or can be made by way of adjustment or tuning, resonant with a transition in said superconducting material and in controlling, in particular enhancing, the superconductivity, and thus the mobility of the charge carriers, resulting in an increased electrical current, in said inorganic or molecular material, by means of strongly coupling said material to the local electromagnetic vacuum field and exploiting the formation of delocalized hybrid states.

The method according to the invention may also comprise or show one or several of the following secondary features or alternatives:
the Q-factor, defined as the ratio of the wavelength of the resonance divided by the half-width of the resonance, of the resonant electromagnetic mode is larger than 10;
the electromagnetic mode is a surface plasmon or a spoof plasmon mode;
the electromagnetic mode is a cavity mode, preferably defined by two opposed mirror structures (for example two parallel planar mirrors);
the reflective structure comprises at least one metallic surface, for example made of a metal film or of two opposed metal films;
the concerned transition in the material is a phonon transition.
the concerned transition in the material is a vibrational transition.

According to an advantageous embodiment of the invention, the method consists more precisely, by means of coupling to local electromagnetic vacuum field and exploiting the resulting rearrangement of the energy levels of the material, in inducing the formation of hybrid light-matter states in the material in order to increase its superconductivity said hybrid states extending over the mode volume of the electromagnetic mode.

In practice, the previously described method can be applied in a functional device comprising said reflective or photonic structure, said device being one of an electric device, an electronic device, an electro-optical device, an optoelectronic device, the superconductivity of which are significantly increased as a result of said method.

The invention also encompasses an electric, an electronic, electro-optical or optoelectronic device, comprising a superconductive material located in or on a reflective or photonic structure,

device characterized in that said structure has an electromagnetic mode which is by design or can be made by way of adjustment or tuning, resonant with a transition in said superconductive material and in controlling, in particular enhancing, the superconductivity and therefore the mobility of the charge carriers, and thus increasing the electrical current, in said superconductive material, by means of strongly coupling said material to the local electromagnetic vacuum field and exploiting the formation of extended macroscopic states in said material, namely states of spatial extension corresponding to the mode volume of the electromagnetic resonance.

Preferably, said device incorporates or makes use of one or several of the previously mentioned secondary features.

Advantageously, the reflective or photonic structure consists of an optical microcavity, preferably a Fabry-Perot cavity, the electromagnetic mode being a cavity mode.

More precisely, the structure may comprise two metallic or dielectric mirrors forming with the superconductive material a sandwich structure, the distance between said mirrors being adjusted to resonate with a phonon or vibration transition of said material, said opposite mirrors being arranged preferably transversally or longitudinally to the direction of displacement of the charge carriers.

Furthermore, the invention also comprises a machine or apparatus able and intended to perform at least one electronic, electro-optic, optoelectronic or optic function, wherein said machine or apparatus comprises at least one device as mentioned before, said device being designed to perform the method set out previously.

In terms of practical embodiments, one can notably refer to and rely on the teachings of the aforementioned PCT publications, namely WO 2013/017961 and WO 2015/008159, which are incorporated in the present specification by reference.

More specifically, the teachings related to the constructions shown in FIGS. 3A and 3B and in FIG. 8 of WO 2015/008159, and the associated description, can be used to put into practice the present invention.

Thus, a device according to the present invention can be realized by replacing the material 2 in FIGS. 3A and 3B or in FIG. 8 of WO 2015/008159 (or US 2016/154258) by a supraconductor material 2 having at least one phonon mode which can be coupled, such as for example C₆₀ Rb₃ or the family of materials related to C₆₀ Rb₂ Cs.

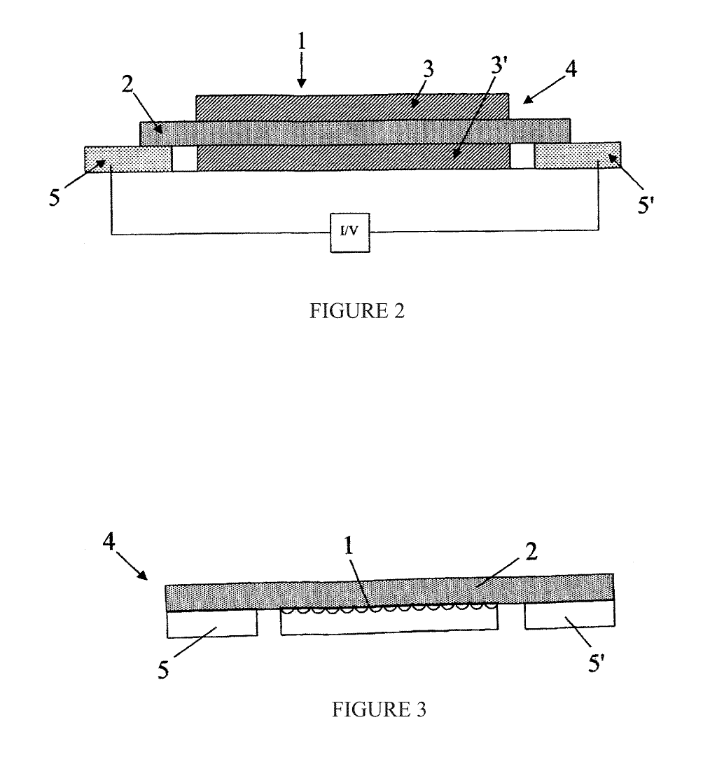

Finally, the invention also encompasses a method, a device and a machine or an apparatus as mentioned in any of the attached claims 1 to 16, and as illustrated schematically by way of two non limitative examples of embodiments in the attached FIGS. 2 and 3.

1. A method to modify the superconductive properties of a potentially or effectively superconductive material comprising the steps of providing a reflective or photonic structure and of placing said superconductive material in or on said structure, the method further comprising providing a structure (1) which has an electromagnetic mode which is by design, or can be made by way of adjustment or tuning, resonant with a transition in said material (2) and in controlling, in particular enhancing, the superconductivity, and thus the mobility of the charge carriers, resulting in a higher operating temperature and an increased electrical current, in said material (2), by means of strongly coupling said material (2) to the local electromagnetic vacuum field and exploiting the formation of states of spatial extension corresponding to the mode volume of the electromagnetic resonance.

2. A method according to claim 1, wherein the Q-factor, defined as the ratio of the wavelength of the resonance divided by the half-width of the resonance, of the resonant electromagnetic mode is comprised between 10 and 1 000.

3. A method according to claim 1, wherein the electromagnetic mode is a surface or spoof plasmon mode.

4. A method according to claim 1, wherein the electromagnetic mode is a cavity mode.

5. A method according to claim 4, wherein the cavity mode is defined by two opposed mirror structures.

6. A method according to claim 1, wherein the reflective structure comprises at least one metallic surface, for example made of a metal film or of two opposed metal films (3, 3′).

7. A method according to claim 1, wherein the concerned transition of the material is a photon transition.

8. A method according to claim 1, wherein the concerned transition of the material is a vibrational transition.

9. A method according to claim 1, further comprising, by means of coupling to local electromagnetic vacuum field and exploiting the resulting rearrangement of the energy levels of the material, in inducing the formation of hybrid light-matter states in the superconductive material in order to increase its superconductivity operating temperature and the carrier mobility, said hybrid states extending over the mode volume of the electromagnetic mode.

10. A method according to claim 1, wherein the method is applied in a functional device comprising said reflective or photonic structure, said device being one of an electric device, an electronic device, an electro-optical device, an optoelectronic device.

11. An electronic, electro-optical or optoelectronic device comprising superconductive material located in or on a reflective or photonic structure,
device (4) wherein said structure (1) has an electromagnetic mode which is by design or can be made by way of adjustment or tuning, resonant with a transition in said material (2) and in controlling, in particular enhancing, the superconductivity and increasing its operating temperature, and thus increasing the temperature at which the electrical current circulates with little or no resistance, in said material (2), by means of strongly coupling said material (2) to the local electromagnetic vacuum field and exploiting the formation of extended macroscopic states in said material, namely states of spatial extension corresponding to the mode volume of the electromagnetic mode involved.

12. A device according to claim 11, wherein the concerned transition is one of a phonon or a vibrational transition.

13. A device according to claim 11, wherein the reflective or photonic structure (1) comprises plasmonic structures, the electromagnetic mode being a spoof plasmon mode.

14. A device according to claim 11 wherein the reflective or photonic structure (1) consists of an optical microcavity, preferably a Fabry-Perot cavity, the electromagnetic mode being a cavity mode.

15. A device according to claim 11, wherein the reflective structure (1) comprises two metallic or dielectric mirrors (3 and 3′) forming with the material (2) a sandwich structure, the distance between said mirrors (3 and 3′) being adjusted to resonate with a phonon transition in said material (2).

16. Machine or apparatus able and intended to perform at least one electronic, electro-optic, optoelectronic or optic function, wherein said machine or apparatus comprises at least one device according to claim 11, said device being designed to perform a method to modify the superconductive properties of a potentially or effectively superconductive material comprising the steps of providing a reflective or photonic structure and of placing said superconductive material in or on said structure, the method further comprising
providing a structure (1) which has an electromagnetic mode which is by design, or can be made by way of adjustment or tuning, resonant with a transition in said material (2) and in controlling, in particular enhancing, the superconductivity, and thus the mobility of the charge carriers, resulting in a higher operating temperature and an increased electrical current, in said material (2), by means of strongly coupling said material (2) to the local electromagnetic vacuum field and exploiting the formation of states of spatial extension corresponding to the mode volume of the electromagnetic resonance.

17. The method of claim 2, wherein the Q-factor is between 10 and 100.

18. The method of claim 5, wherein the opposed mirror structures are two parallel planar mirrors.

19. The method of claim 9, wherein the hybrid states extend over an area extending at least 1 μm in all directions.

20. The device of claim 15, wherein the opposite mirrors are arranged transversally or longitudinally to the direction of displacement of the current carriers or forming simultaneously electrodes.
